(19) United States
(12) Patent Application Publication
(10) Pub. No.: US 2026/0032896 A1
(43) Pub. Date: Jan. 29, 2026

(54) ACTIVE AREA FORMATION IN MEMORY DEVICES

(71) Applicant: Micron Technology, Inc., Boise, ID (US)

(72) Inventors: Bingwu Liu, Meridian, ID (US); Shivani Srivastava, Boise, ID (US); Dan Mihai Mocuta, Boise, ID (US); Deokhan Bae, Meridian, ID (US)

(21) Appl. No.: 19/272,545

(22) Filed: Jul. 17, 2025

Related U.S. Application Data
(60) Provisional application No. 63/675,950, filed on Jul. 26, 2024.

(51) Int. Cl. H10B 12/00; H01L 21/02; H01L 21/3105; H01L 21/762; H10D 64/66

(52) U.S. Cl. CPC H10B 12/50; H01L 21/0228; H01L 21/31053; H01L 21/76224; H10B 12/01; H10D 64/662

(57) ABSTRACT

A process can be implemented to form adjacent transistors separated by a shallow trench isolation (STI), where the STI is formed after forming gates and sources/drains of the transistors. The STI can be formed by an active area cut using a mask to form a rectangular opening for filling with a STI dielectric. Using an active area mask providing a rectangular-like shape after forming gate stacks and source/drains, a memory device can be constructed having transistors separated by a STI having a recess from active areas of the transistors by at most 50 nm.

### PRIORITY APPLICATION

This application claims the benefit of priority to U.S. Provisional Application Ser. No. 63/675,950, filed Jul. 26, 2024, which is incorporated herein by reference in its entirety.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates shows two complementary metal-oxide semiconductor devices separated by a shallow trench isolation, in accordance with various embodiments.

FIG. 2 illustrates another issue for a sense amplifier in the periphery to a memory array of a memory device, in accordance with various embodiments.

FIG. 3 illustrates an approach to address the issue of rounding of active areas between two device structures, in accordance with various embodiments.

FIG. 4 is a flow diagram of features of an example method of forming a memory device, in accordance with various embodiments.

FIG. 5 is a flow diagram of features of an example method of forming a memory device, in accordance with various embodiments.

FIGS. 6-15 illustrate a process flow for active area formation in sections in the periphery to a memory array of a memory device, in accordance with various embodiments.

FIG. 16 is a schematic of an example dynamic random-access memory device that can include an architecture for sense amplifiers of the dynamic random-access memory device, in accordance with various embodiments.

FIG. 17 is a block diagram illustrating an example of a machine upon which one or more embodiments of one or more memory components may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

With scaling of memory array dimensions, the number of memory cells in the memory array can increase. With the increase in the number of memory cells, there can be an increase in the number of devices in the periphery of the memory array to control and maintain the memory cells. Such increase in the number of devices can be addressed in a similar manner to the memory cells by shrinking dimensions in control regions and processing regions in the periphery. Along with shrink of dimensions for a memory array of a memory device, such as a DRAM, the shrinkage in the area of periphery devices, such as sense amplifiers (SAs), in the memory device should be made to meet increased memory cell capacity. Associated with shrinkage in the periphery devices, there is an issue with mismatch of components in the periphery devices such as SAs. The mismatch is a variation of properties and characteristics in constructed devices that are intended to have the same properties and characteristics.

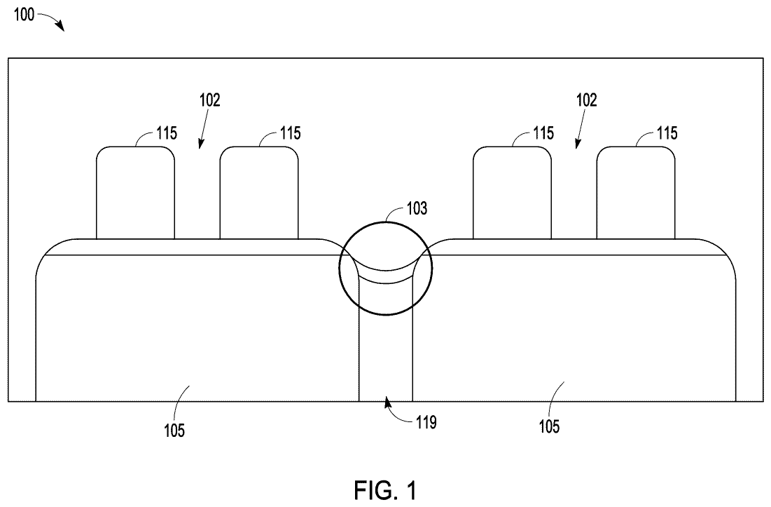

In DRAMs, for example, mismatches can include results from active area rounding and gate corner rounding in transistors in sections of the periphery. FIG. 1 shows a structure 100 having two complementary metal-oxide semiconductor (CMOS) devices 102 separated by a shallow trench isolation (STI) 119. Each CMOS device 102 has two gate stacks 115 on active areas 105. Silicon recess in the shoulder of the active area from formation of STI 119 before dopant implant can cause mismatch in the implant profile in the active areas. Circle 103 shows the rounding of the active areas on each side of STI 119, which can lead to variations of the device on the right with respect to the device on the left when the roundings are different from each other. Further, a silicon-germanium channel (cSiGe) in a p-type SAs (PSA) can make gate etching difficult due to the active area rounding. Additionally, metal residue in an STI between PSAs from construction of a high-k gate (HKMG) can be of concern for those architectures that use HKMGs. A HKMG is a gate comprising a metal located on a high-k dielectric, where a high-k dielectric is a dielectric having a dielectric constant greater than that of silicon dioxide.

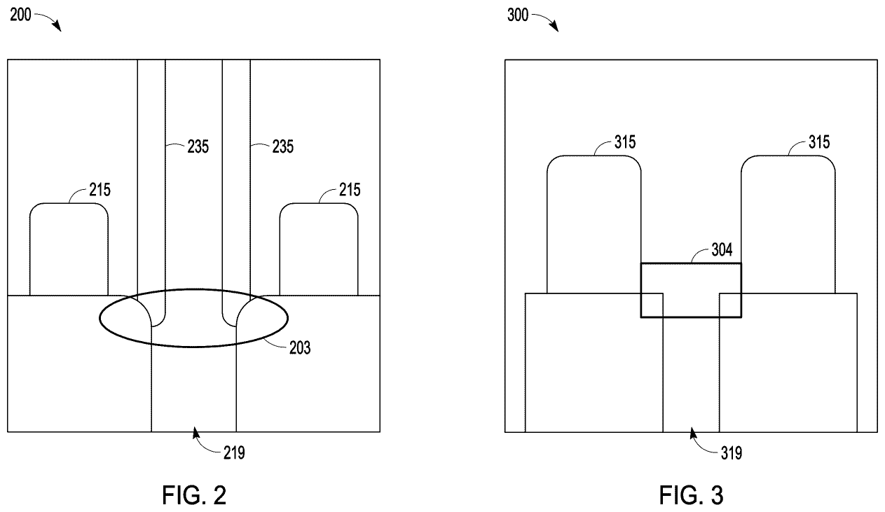

FIG. 2 illustrates, in a structure 200, another issue for a SA in the periphery to a memory array of a memory device. Structure 200 includes contacts 235 on roundings of active areas for gate stacks 215. Circle 203 illustrates that a contact blowout can cause a contact to contact short in a recess, since there is only oxide between the two contacts 235. The recessed active area shoulder associated with gate stacks 215 can also cause implant profile variation which is a key factor for mismatch of the properties of the two gate stacks 215.

FIG. 3 illustrates, in a structure 300, an approach to address the issue of rounding of active areas between two device structures. Structure 300 includes a raised epitaxial region 304 to improve the silicon recess. Given the narrow active area to active area space, an epitaxial process is challenging and may result in short between the two devices due to the extent of the formed raised epitaxial region 304.

In various embodiments, a process can be implemented to form adjacent transistors separated by an STI, where the STI is formed after forming the transistors. The STI can be formed by an active area cut using a mask to form a rectangular opening for filling with a STI dielectric. Using an active area mask providing a rectangular-like shape after forming gate stacks and source/drains, a memory device can be constructed having transistors separated by a STI having a recess from active areas of the transistors by at most 50 nm.

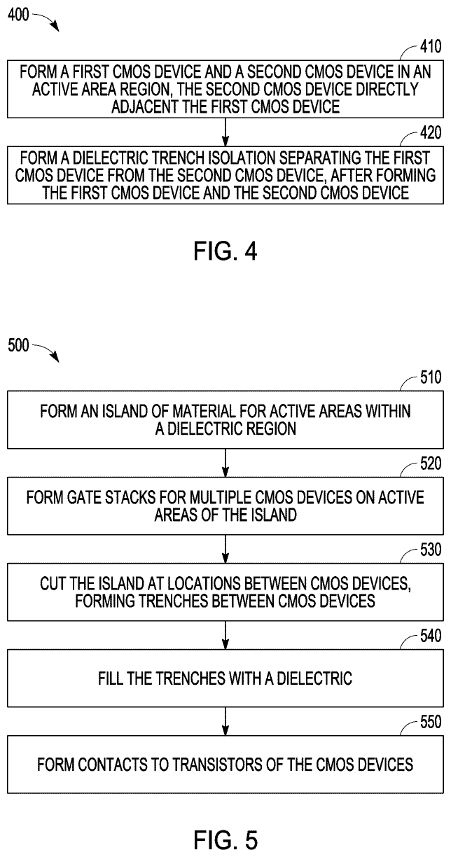

FIG. 4 is a flow diagram of features of an embodiment of an example method 400 of forming a memory device. At 410, a first CMOS device is formed and a second CMOS device is formed in an active area region. The active region can be a relatively long continuous strip of material for active areas on which more than two CMOS devices can be structured. The second CMOS device is directly adjacent the first CMOS device. At 420, a dielectric trench isolation is formed in the active area region separating the first CMOS device from the second CMOS device, after forming the first CMOS device and the second CMOS device.

Variations of method 400 or methods similar to method 400 can include a number of different embodiments that may be combined depending on the application of such methods or the architecture or process flow of an integrated circuit for which such methods are implemented. Such methods can include forming the dielectric trench isolation after forming source/drain regions of the first CMOS device and the second CMOS device.

Variations of method 400 or methods similar to method 400 can include forming the dielectric trench isolation by forming a trench between the first CMOS device and the second CMOS device; and filling the trench with a low-k dielectric. The trench can be formed using an active area mask designed to construct an opening with straight edges to limit or eliminate roundings at the tops of the trench. The trench can be filled using atomic layer deposition. The low-k dielectric can include a nitride.

FIG. 5 is a flow diagram of features of an embodiment of an example method 500 of forming a memory device. At 510, an island of material for active areas is formed within a dielectric region. The island can be relatively long such that multiple devices with separate active areas can be formed in later processing. At 520, gate stacks are formed for multiple CMOS devices on active areas of the island. HKMGs can be formed in the gate stacks. At 530, the island is cut at locations between CMOS devices, forming trenches between CMOS devices. At 540, the trenches are filled with a dielectric. At 550, contacts are formed to transistors of the CMOS devices.

Variations of method 500 or methods similar to method 500 can include a number of different embodiments that may be combined depending on the application of such methods or the architecture or process flow of an integrated circuit for which such methods are implemented. Cutting the island can include using a mask structured for constructing a rectangular shape, Cutting the island can include forming the trench with a rectangular shape. Cutting the island can include removing material between a transistor of one CMOS device and a transistor of a directly adjacent CMOS device on the island such that an opening is formed having a width at top of the island equal to a width of the island.

Variations of method 500 or methods similar to method 500 can include forming a low-k dielectric in the trenches to fill the trenches. The trenches can be filled using atomic layer deposition. The low-k dielectric can include a nitride. A chemical mechanical planarization procedure can be performed on top surfaces of the low-k dielectric. Filling the trenches can form dielectric trench isolations between directly adjacent CMOS devices such that top surfaces of the active areas of the CMOS devices extend to the dielectric trench isolations. Interfaces of the extended top surfaces at the dielectric trench isolations can be recessed at most 50 nm. The interfaces of the extended top surfaces and the dielectric trench isolations can be recessed by 0 nm.

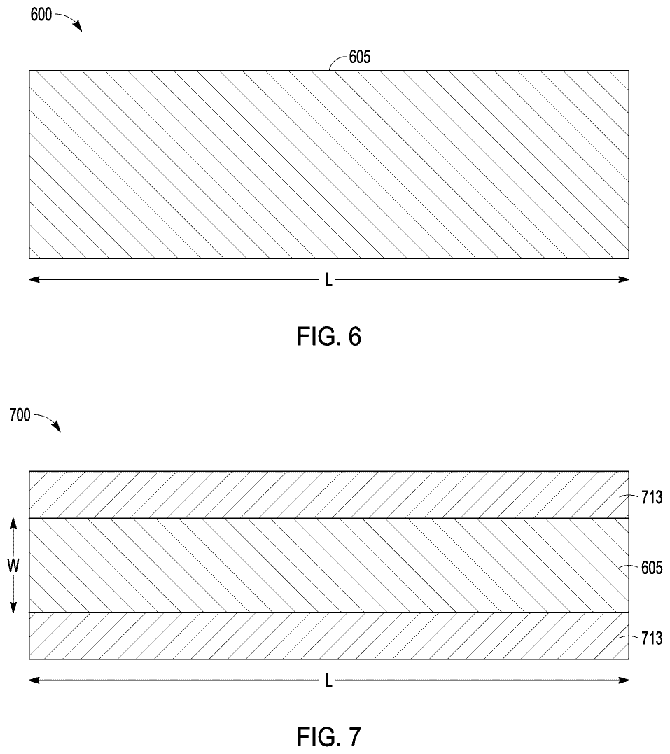

FIGS. 6-15 illustrate a process flow for active area formation in sections in the periphery to a memory array of a memory device. The memory device can be, but is not limited to, a DRAM device. The active area formation can be performed for devices in SAs in the periphery or in pitch devices in the periphery. Pitch devices are control oriented devices in the periphery for operating on memory cells in the array the memory device.

FIG. 6 illustrates a cross-section of structure 600 after forming an island 605 of material for active areas in the periphery of a memory array of a memory device. Island 605 for active areas can have length, L, providing area for forming a significant number of transistors. Island 605 can be structured as a relatively long length. The transistors can be structured in pairs forming CMOS devices. Island 605 can be composed of, but is not limited to, silicon.

FIG. 7 illustrates a structure 700 representing a top view of structure 600 of FIG. 6, which shows island 605 within a dielectric region 713. Island 605 of structure 700 has a rectangular shape. The rectangular shape can provide a starting mechanism to avoid mismatch of structures being formed on island 605, for example, when forming sources and drains in island 605 of active areas.

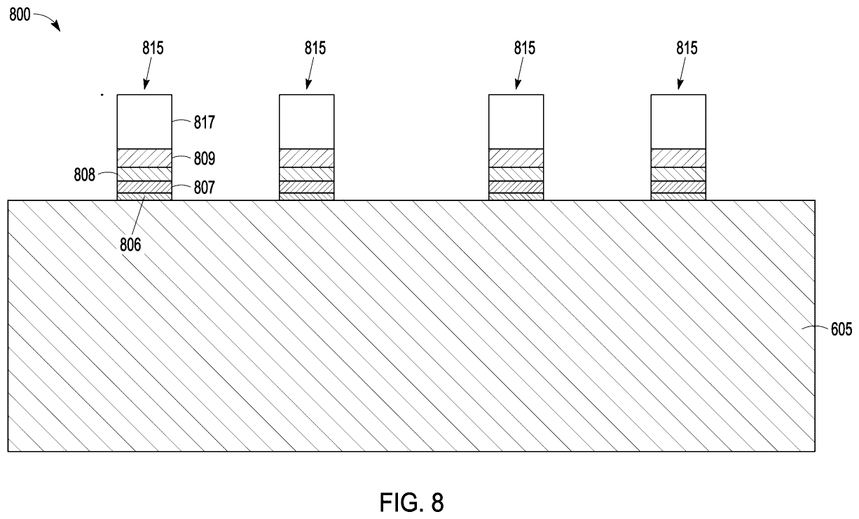

FIG. 8 illustrates a cross-section of a structure 800 after processing structure 600 of

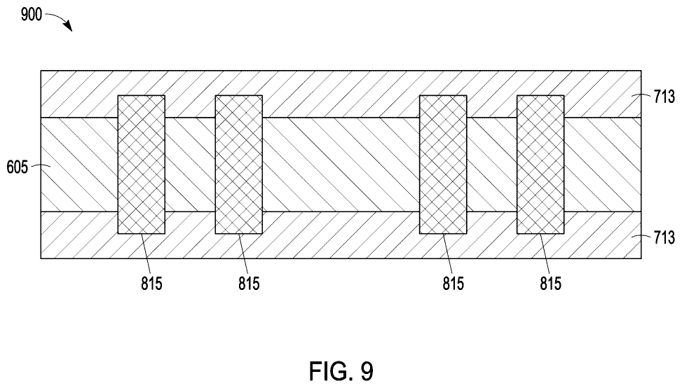

FIG. 6. Gate stacks 815 have been formed on island 605. Though four gate stacks have been formed, the number of gate stacks 815 can be significantly larger than four. Gate stacks 815 can be formed in pairs for forming CMOS devices. Gate stacks 815 of a CMOS device can be separated by a shorter distance than distance than the distance between adjacent CMOS devices as illustrated in structure 900 of FIG. 9 that provides a top view representation of structure 800 of FIG. 8. Each gate stack 815 of FIG. 8 can include a dielectric 806 on island 605 for the active areas, a HKMG 807 on dielectric 806, a polysilicon region 808, and a contact 809 on polysilicon region 808, with a dielectric gap 817. Using HKMG 807, dielectric 806 can be a thin layer, relative to the high-k dielectric, of silicon oxide. Alternatively, gate stack 815 can be constructed without dielectric 806 or a polysilicon gate can be used in place of HKMG 807. Other variations can include, but are not limited to, gate stack 815 structured without polysilicon region 808.

At this point in the process flow, gate stacks for multiple CMOS devices formed using island 605 for active areas have not been separated to isolate the CMOS devices from each other. STIs have not been formed to provide the isolations. With no STI having been formed during gate formation of gate stacks 815, concerns regarding residue formation associated with STI formation before gate stack formation have been avoided.

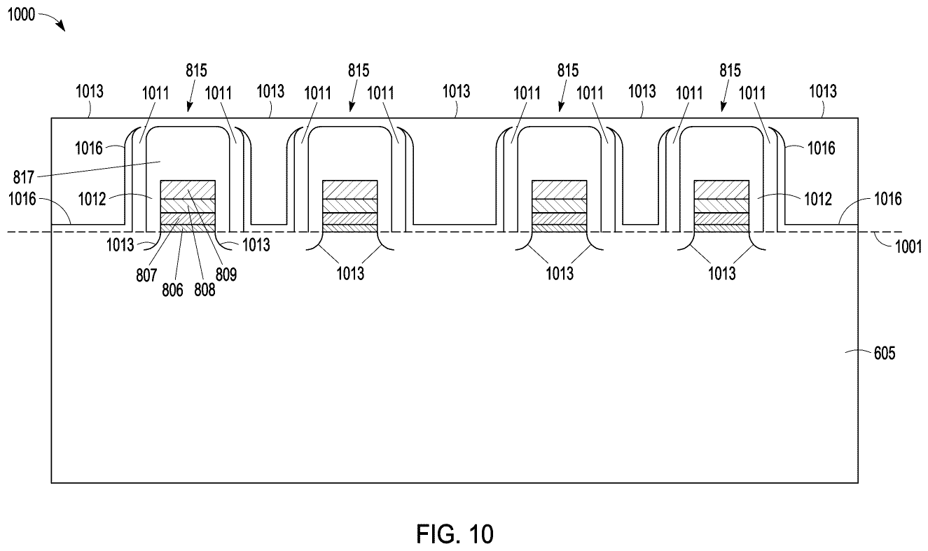

FIG. 10 illustrates a cross-section of a structure 1000 after processing structure 800 of FIG. 8. Sources/drains 1014 for gate stacks 815 have been formed along with formation of an interlayer dielectric (ILD) 1013. A spacer for each gate stack 815 can include multiple dielectric layers. Dielectric spacers 1012 has been formed on and contacting gate stacks 815 and dielectric regions 1011 has been formed on and contacting dielectric spacers 1012. A dielectric layer 1016 has been formed on and contacting dielectric region 1011 and on and contacting surface 1001 of island 605 for active areas. ILD 1013 and dielectric regions 1011 can be, but are not limited to, oxides such as but not limited to silicon oxide. Dielectric spacers 1012 and dielectric layer 1016 can be, but are not limited to, a nitride. Dielectric layer 1016 can have a composition similar to the composition of dielectric gap 817. With sources/drains 1014 formed prior to separating resulting pairs of transistors having gate stacks 815, doping to form the sources and drains of the transistors of the CMOS devices, at this point in the process, avoids mis-matches or variations of properties among the CMOS devices that accompanies a process that forms a STI before forming gate stacks 815 and associated source/drains.

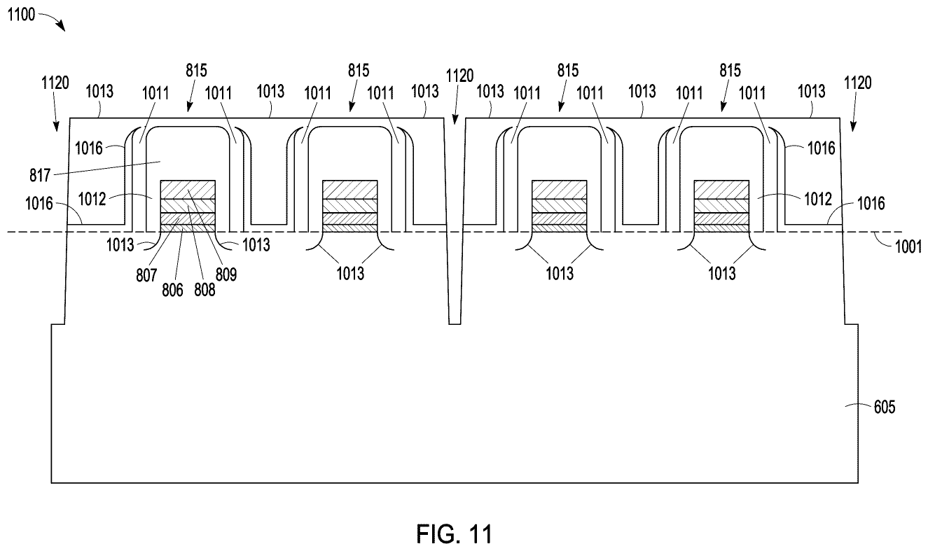

FIG. 11 illustrates a cross-section of a structure 1100 after processing structure 800 of FIG. 10. An active area cut has been performed creating a trench 1120. The active area cut provides isolation between pairs of gate stacks 815 being processed to form CMOS devices. Trench 1120 can be formed using a mask for the active area cut, where the mask is designed to produce a specified shape for the horizontal plane of trench 1120. The specified shape can be a rectangle in the plane of the top of island 605 for active areas.

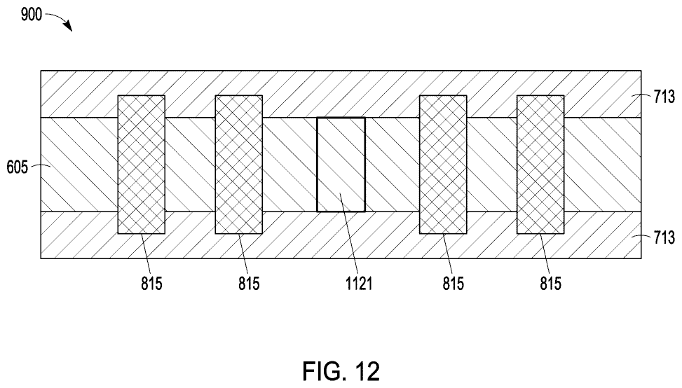

FIG. 12 illustrates a structure 1200 that provides a top view representation of structure 1100 of FIG. 11. The separation provided by the active cut can provide trench 1120 with a planar shape 1121 at surface 1001 similar to island 605 of active areas. Shape 1121 can have a width W being the same as the width of island 605. Island 605 for active areas and shape 1121 can be, but is not limited, to a rectangle.

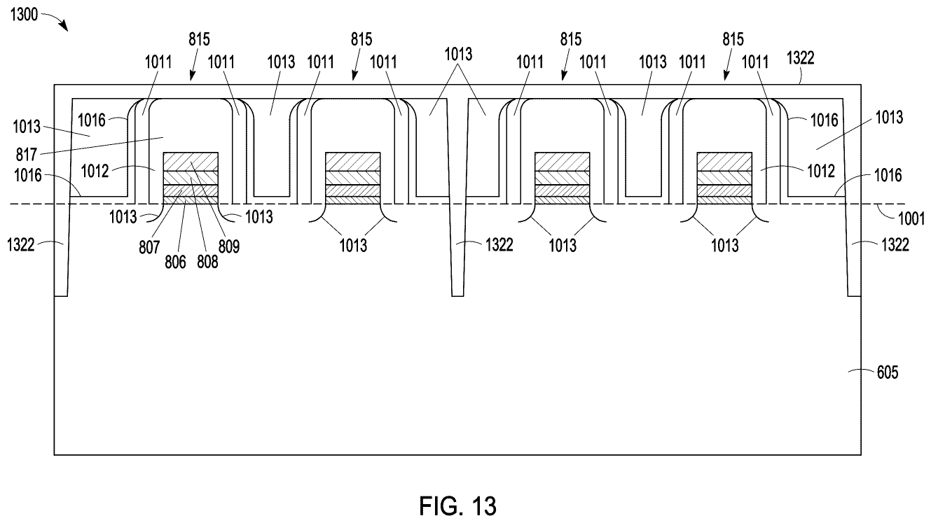

FIG. 13 illustrates a cross-section of a structure 1300 after processing structure 1100 of FIG. 11. The gap fill of trench 1120 has been filled with dielectric 1322. Th top surface of structure 1100 has been covered by dielectric 1322. Dielectric 1322 can be a low-k dielectric. A low-k dielectric is a dielectric having a dielectric constant equal to or less than 7.5. The low-k dielectric can be, but is not limited to, one or more of a nitride or an oxide. The gap fill can be performed by atomic layer deposition (ALD). However, techniques other than ALD can be used.

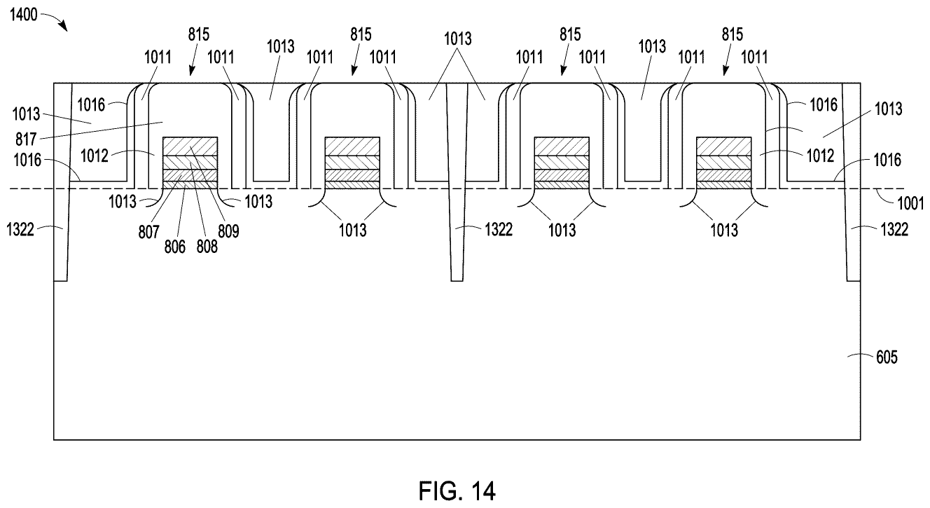

FIG. 14 illustrates a cross-section of a structure 1400 after processing structure 1300 of FIG. 13. A chemical mechanical planarization (CMP) process has been applied to the top surface of structure 1300, removing the horizontal portions of dielectric 1322. Dielectric 1322 remains in what was trench 1120, forming STIs between directly adjacent transistors having gate stacks 815, where the directly adjacent transistors are transistors of different CMOS devices formed using island 605 for active areas. Use of the CMP process can be optional.

Formation of STIs after formation of gate stacks 815 and formation of source/drains under gate stacks 815 after than before formation of gate stacks 815 can result in less or no silicon recess of the island 605 of active areas at the interfaces with the STIs. Such a recess is a recess of the level at surface 1001 of the island 605 for the active areas. The formation of the STIs associated with structures 1300 and 1400 between directly adjacent CMOS devices such that top surface of the active areas of the CMOS devices extends to the adjacent STIs can be constructed with interfaces of the extended top surfaces at the STIs recessed at most 50 nm. The interfaces of the extended top surfaces and the STIs may be recessed by 0 nm.

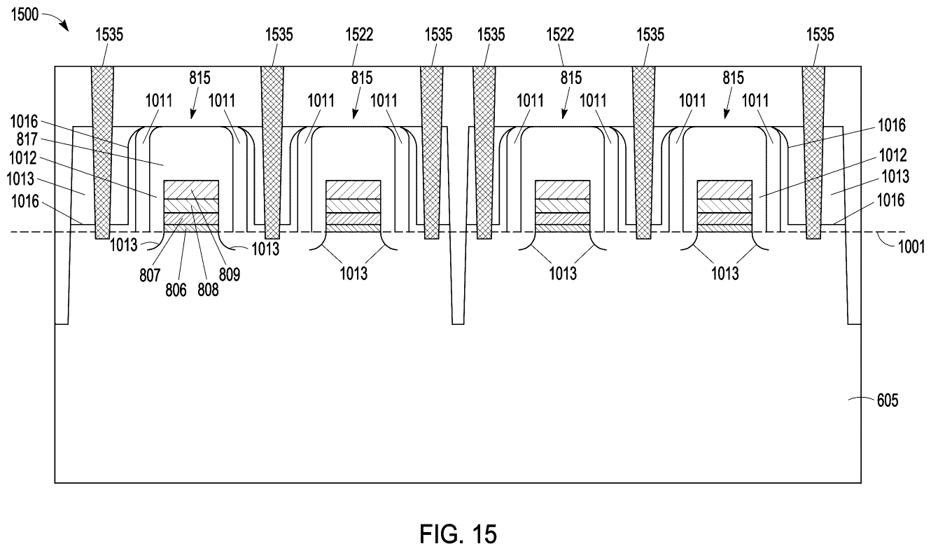

FIG. 15 illustrates a cross-section of a structure 1400 after processing structure 1400 of FIG. 14. Contacts 1535 have been formed to the transistors having gate stacks 815. A dielectric cap 1522 has been formed between contacts 1535 and on and contacting the top surface of structure 1400. The dielectric cap 1522 can have the same composition as dielectric 1322 in the STIs. Dielectric cap 1522 can be, but is not limited to, a nitride. Dielectric 1322 of the STIs blocks contacts 1535 of different CMOS devices near a respective STI from shorting to each other.

Various deposition techniques for components of structures 600-1500 in the process flow of FIGS. 6-15 can be used that are typical for the material being formed, the dimensions of the material being formed, and the architecture in which the material is being formed. Selective etching can be used to remove selected regions in some of the processing discussed herein. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in forming STIs using an active area mask on an island for active areas after forming gate stacks and source/drains associated with the gate stacks, as taught herein.

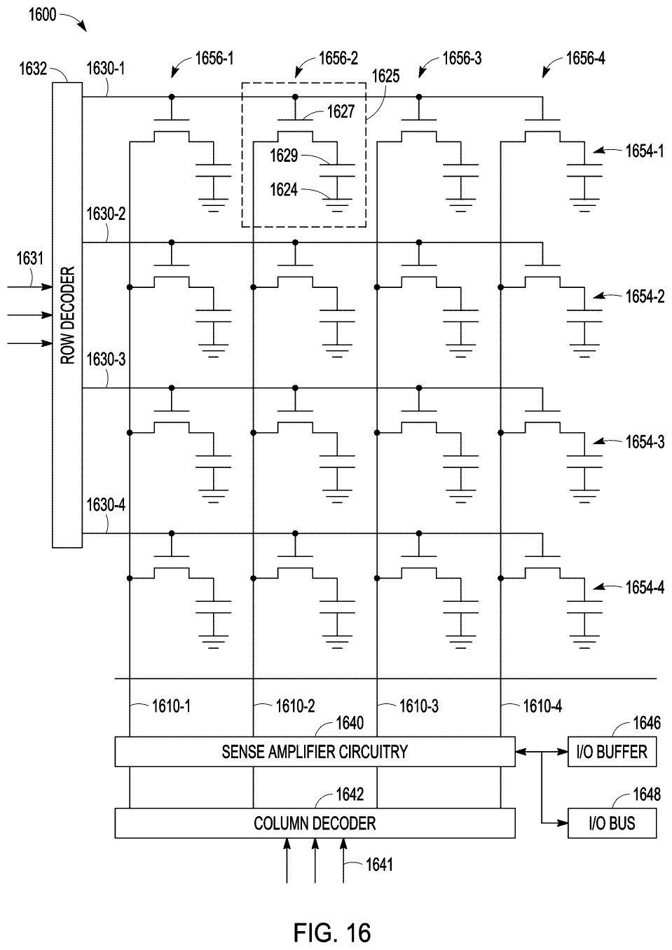

FIG. 16 is a schematic of an embodiment of an example DRAM device 1600 that can include an architecture for sense amplifiers of DRAM device 1600 having STIs using an active area mask on an island for active areas after forming gate stacks and source/drains associated with the gate stacks, as taught herein. DRAM device 1600 can include an array of memory cells 1625 (only one being labeled in FIG. 16 for ease of presentation) arranged in rows 1654-1, 1654-2, 1654-3, and 1654-4 and columns 1656-1, 1656-2, 1656-3, and 1656-4. For simplicity and case of discussion, the array is shown in only two dimensions, but the array can be extended into the third dimension. Further, while only four rows 1654-1, 1654-2, 1654-3, and 1654-4 and four columns 1656-1, 1656-2, 1656-3, and 1656-4 of four memory cells are illustrated, DRAM devices like DRAM device 1600 can have significantly more memory cells 1625 (e.g., tens, hundreds, or thousands of memory cells) per row or per column.

Each memory cell 1625 can include a single transistor 1627 and a single capacitor 1629, which is commonly referred to as a 1T1C (one-transistor-one capacitor cell). One plate of capacitor 1629, which can be termed the “node plate,” is connected to the drain terminal of transistor 1627, whereas the other plate of the capacitor 1629 is connected to a reference 1624, which can be ground. Each capacitor 1629 within the array of 1T1C memory cells 1625 typically serves to store one bit of data, and the respective transistor 1627 serves as an access device to write to or read from storage capacitor 1629.

The transistor gate terminals within each row of rows 1654-1, 1654-2, 1654-3, and 1654-4 are portions of respective WLs 1630-1, 1630-2, 1630-3, and 1630-4 (for example, word lines), and the transistor source terminals within each of columns 1656-1, 1656-2, 1656-3, and 1656-4 are electrically connected to respective DLs 1610-1, 1610-2, 1610-3, and 1610-4 (for example bit lines). A row decoder 1632 can selectively drive the individual WLs 1630-1, 1630-2, 1630-3, and 1630-4, responsive to row address signals 1631 input to row decoder 1632. Driving a given WL at a high voltage causes the access transistors within the respective row to conduct, thereby connecting the storage capacitors within the row to the respective DLs, such that charge can be transferred between the DLs and the storage capacitors for read or write operations. Both read and write operations can be performed via sense amplifier circuitry 1640, which can transfer bit values between the memory cells 1625 of the selected row of the rows 1654-1, 1654-2, 1654-3, and 1654-4 and input/output buffers 1646 (for write/read operations) or external input/output data buses 1648.

A column decoder 1642 responsive to column address signals 1641 can select which of the memory cells 1625 within the selected row is read out or written to. Alternatively, for read operations, the storage capacitors 1629 within the selected row may be read out simultaneously and latched, and the column decoder 1642 can then select which latch bits to connect to the output data bus 1648. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DLs 1610-1, 1610-2, 1610-3, and 1610-4 can be constructed as metal DLs having localized widenings about DL contacts to access transistors 1627 of memory cells 1625 of a memory array of DRAM device 1600, as taught herein. The metal can be the same for DLs 1610-1, 1610-2, 1610-3, and 1610-4 and the metal contacts to these DLs and can be formed at the same portion of the fabrication process flow.

DRAM device 1600 may be implemented as an integrated circuit within a package that includes pins for receiving supply voltages (e.g., to provide the source and gate voltages for the transistors 1627) and signals (including data, address, and control signals). FIG. 16 depicts DRAM device 1600 in simplified form to illustrate basic structural components, omitting many details of the memory cells 1625 and associated WLs 1630-1, 1630-2, 1630-3, and 1630-4 and DLs 1610-1, 1610-2, 1610-3, and 1610-4 as well as the peripheral circuitry. For example, in addition to the row decoder 1632 and column decoder 1642, sense amplifier circuitry 1640, and buffers 1646, DRAM device 1600 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

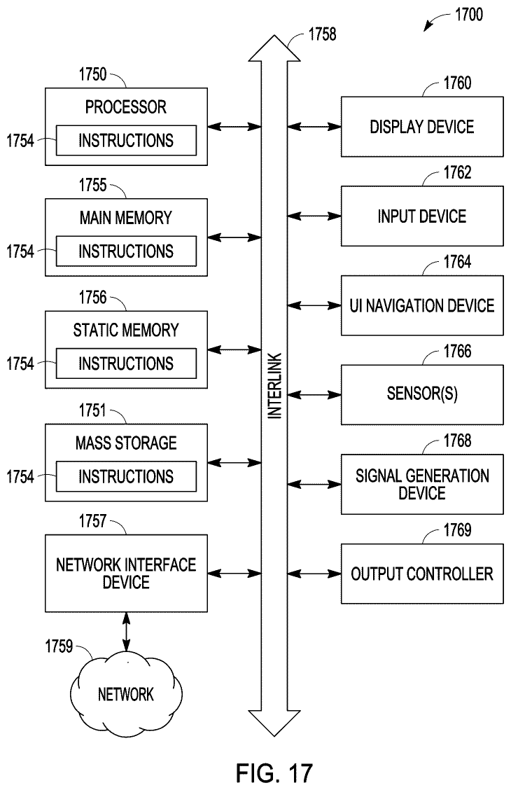

FIG. 17 illustrates a block diagram of an example machine 1700 having one or more embodiments of memory components discussed herein. In alternative embodiments, machine 1700 may operate as a standalone device or may be connected (e.g., networked) to other machines. In a networked deployment, machine 1700 may operate in the capacity of a server machine, a client machine, or both in server-client network environments. In an example, machine 1700 may act as a peer machine in peer-to-peer (P2P) (or other distributed) network environment. Machine 1700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 1700 can include one or more memory devices having structures as discussed with respect to structure 1500 of FIG. 15.

Machine (e.g., computer system) 1700 may include a hardware processor 1750 (e.g., a CPU, a GPU, a hardware processor core, or any combination thereof), a main memory 1755 and a static memory 1756, some or all of which may communicate with each other via an interlink (e.g., bus) 1758. Machine 1700 may further include a display device 1760, an alphanumeric input device 1762 (e.g., a keyboard), and a user interface (UI) navigation device 1764 (e.g., a mouse). In an example, display device 1760, alphanumeric input device 1762, and UI navigation device 1764 may be a touch screen display. Machine 1700 may additionally include a mass storage (e.g., drive unit) 1751, a signal generation device 1768 (e.g., a speaker), a network interface device 1757, and one or more sensors 1766, such as a global positioning system (GPS) sensor, compass, accelerometer, or other sensor. Machine 1700 may include an output controller 1769, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 1700 may include a machine-readable medium on which is stored one or more sets of data structures or instructions 1754 (for example, software or microcode) embodying or utilized by machine 1700. Instructions 1754 may also reside, completely or at least partially, within main memory 1755, within static memory 1756, within mass storage 1751, or within hardware processor 1750 during execution thereof by machine 1700. In an example, one or any combination of hardware processor 1750, main memory 1755, static memory 1756, or mass storage 1751 may constitute machine-readable medium. Machine-readable medium can be a single medium or multiple media (e.g., a centralized or distributed database, or associated caches and servers) configured to store one or more instructions 1754.

The term “machine-readable medium” may include any medium that is capable of storing instructions for execution by machine 1700 and that cause machine 1700 to perform any one or more of the techniques for which machine 1700 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 1754 (e.g., software, programs, microcode, an operating system (OS), etc.) or other data stored on mass storage 1751, can be accessed by main memory 1755 for use by processor 1750. Main memory 1755 (e.g., DRAM) is typically fast, but volatile, and thus a different type of storage than mass storage 1751 (e.g., an SSD), which is suitable for long-term storage, including while in an “off” condition. Instructions 1754 or data in use by a user or machine 1700 are typically loaded in main memory 1755 for use by processor 1750. When main memory 1755 is full, virtual space from mass storage 1751 can be allocated to supplement main memory 1755; however, because mass storage 1751 is typically slower than main memory 1755, and write speeds are typically at least twice as slow as read speeds, use of virtual memory can greatly reduce user experience due to storage device latency (in contrast to main memory 1755, e.g., DRAM). Further, use of mass storage 1751 for virtual memory can greatly reduce the usable lifespan of mass storage 1751.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 1754 may further be transmitted or received over a network 1759 using a transmission medium via network interface device 1757 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1757 may include one or more physical jacks (e.g., Ethernet, coaxial, or phone jacks) or one or more antennas to connect to the communications network 1726. In an example, network interface device 1757 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 1700 or data to or from machine 1700. The transportation can include using digital or analog communications signals that can be transmitted over the transmission medium to facilitate communication of such software or data.

The following are example embodiments of devices and methods, in accordance with the teachings herein.

An example memory device 1 can comprise a first transistor in a periphery to an array of memory cells, the first transistor having a gate stack on a top surface of an active area of the first transistor, interface of the gate stack and the top surface of the first transistor at a first level; a second transistor in the periphery to the array of memory cells, the second transistor having a gate stack on a top surface of an active area of the second transistor, the second transistor directly adjacent the first transistor; and a dielectric trench isolation between the first transistor and the second transistor such that the top surface of the active area of the first transistor extends to the dielectric trench isolation with an interface of the extended top surface at the dielectric trench isolation recessed from the first level by at most 50 nm.

An example memory device 2 can include features of example memory device 1 and can include the interface of the extended top surface and the dielectric trench isolation is recessed from the first level by 0 nm.

An example memory device 3 can include features of any of the preceding example memory devices and can include the first transistor being a transistor of a complementary metal-oxide semiconductor (CMOS) device and the second transistor being a transistor of another CMOS device.

An example memory device 4 can include features of any of the preceding example memory devices and can include the first transistor and the second transistor being located in a sense amplifier in the periphery.

An example memory device 5 can include features of any of the preceding example memory devices and can include the first transistor and the second transistor being located in a pitch device in the periphery.

In an example memory device 6, any of the memory devices of example memory devices 1 to 5 may include memory devices incorporated into an electronic apparatus further comprising a host processor or memory controller and a communication bus extending between the host processor/memory controller and the memory device.

In an example memory device 7, any of the memory devices of example memory devices 1 to 6 may be modified to include any structure presented in another of example memory device 1 to 6.

In an example memory device 8, any apparatus associated with the memory devices of example memory devices 1 to 7 may further include a machine-readable storage device configured to store instructions as a physical state, wherein the instructions may be used to perform one or more operations of the apparatus.

In an example memory device 9, any of the memory devices of example memory devices 1 to 8 may be operated in accordance with any of the below example methods 1 to 9 and methods 10 to 23.

An example method 1 of forming a memory device can comprise forming a first CMOS device and a second CMOS device in an active area region, the second CMOS device directly adjacent the first CMOS device; and forming a dielectric trench isolation separating the first CMOS device from the second CMOS device, after forming the first CMOS device and the second CMOS device.

An example method 2 of forming a memory device can include features of example method 1 of forming a memory device and can include forming the dielectric trench isolation after forming source/drain regions of the first CMOS device and the second CMOS device.

An example method 3 of forming a memory device can include features of any of the preceding example methods of forming a memory device and can include forming the dielectric trench isolation to include: forming a trench between the first CMOS device and the second CMOS device; and filling the trench with a low-k dielectric.

An example method 4 of forming a memory device can include features of example method 3 of forming a memory device and any of the preceding example methods of forming a memory device and can include filling the trench using atomic layer deposition.

An example method 5 of forming a memory device can include features of example method 3 of forming a memory device and any of the preceding example methods of forming a memory device and can include the low-k dielectric to include a nitride.

In an example method 6, any of the example methods 1 to 5 of forming a memory device may be performed in forming an electronic apparatus further comprising a host processor and a communication bus extending between the host processor and a memory system.

In an example method 7 of forming a memory device, any of the example methods 1 to 6 of forming a memory device may be modified to include operations set forth in any other of example methods 1 to 6.

In an example method 8 of forming a memory device, any of the example methods 1 to 7 of forming a memory device may be implemented at least in part through use of instructions stored as a physical state in one or more machine-readable storage devices.

An example method 9 of forming a memory device can include features of any of the preceding example methods 1 to 8 of forming a memory device and can include performing functions associated with any features of example memory devices 1 to 9.

An example method 10 of forming a memory device can comprise forming an island for active areas within a dielectric region; forming gate stacks for multiple CMOS devices on active areas of the island; cutting the island at locations between CMOS devices, forming trenches between CMOS devices; filling the trenches with a dielectric; and forming contacts to transistors of the CMOS devices.

An example method 11 of forming a memory device can include features of example method 10 of forming a memory device and can include forming the gate stacks to include forming high-k gates.

An example method 12 of forming a memory device can include features of any of the preceding example methods 10 to 11 of forming a memory device and can include cutting the island to include forming the trench with a rectangular shape.

An example method 13 of forming a memory device can include features of any of the preceding example methods 10 to 12 of forming a memory device and can include cutting the island to include removing material between a transistor of one CMOS device and a transistor of a directly adjacent CMOS device on the island such that an opening is formed having a width at top of the island equal to a width of the island.

An example method 14 of forming a memory device can include features of any of the preceding example methods 10 to 13 of forming a memory device and can include filling the trenches to include forming a low-k dielectric in the trenches.

An example method 15 of forming a memory device can include features of example method 14 of forming a memory device and any of the preceding example methods of forming a memory device 10 to 13 and can include filling the trenches using atomic layer deposition.

An example method 16 of forming a memory device can include features of example method 14 of forming a memory device and any of the preceding example methods 10 to 13 and 15 and can include the low-k dielectric to include a nitride.

An example method 17 of forming a memory device can include features of example method 14 of forming a memory device and any of the preceding example methods 10 to 13 and 15 to 16 of forming a memory device and can include performing a chemical mechanical planarization procedure on top surfaces of the low-k dielectric.

An example method 18 of forming a memory device can include features of any of the preceding example methods 10 to 17 of forming a memory device and can include filling the trenches forming dielectric trench isolations between directly adjacent CMOS devices such that top surfaces of the active areas of the CMOS devices extend to the dielectric trench isolations with interfaces of the extended top surfaces at the dielectric trench isolations are recessed at most 50 nm.

An example method 19 of forming a memory device can include features of example method 18 of forming a memory device and any of the preceding example methods 10 to 17 of forming a memory device and can include the interfaces of the extended top surfaces and the dielectric trench isolations being recessed by 0 nm.

In an example method 20 of forming a memory device, any of the example methods 10 to 19 of forming a memory device may be performed in forming an electronic apparatus further comprising a host processor and a communication bus extending between the host processor and a memory system.

In an example method 21 of forming a memory device, any of the example methods 10 to 20 of forming a memory device may be modified to include operations set forth in any other of example methods 10 to 20 of forming a memory device.

In an example method 22 of forming a memory device, any of the example methods 10 to 22 of forming a memory device may be implemented at least in part through use of instructions stored as a physical state in one or more machine-readable storage devices.

An example method 23 of forming a memory device can include features of any of the preceding example methods 10 to 22 of forming a memory device and can include performing functions associated with any features of example memory devices 1 to 9.

An example machine-readable storage device storing instructions, that when executed by one or more processors, cause a machine to perform operations, can comprise instructions to perform functions associated with any features of example memory devices 1 to 9 or perform form methods associated with any features of example methods 1 to 9 of forming a memory device or example methods 10 to 23 of forming a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a first transistor in a periphery to an array of memory cells, the first transistor having a gate stack on a top surface of an active area of the first transistor, interface of the gate stack and the top surface of the first transistor at a first level;
a second transistor in the periphery to the array of memory cells, the second transistor having a gate stack on a top surface of an active area of the second transistor, the second transistor directly adjacent the first transistor; and
a dielectric trench isolation between the first transistor and the second transistor such that the top surface of the active area of the first transistor extends to the dielectric trench isolation with an interface of the extended top surface at the dielectric trench isolation recessed from the first level by at most 50 nm.

2. The memory device of claim 1, wherein the interface of the extended top surface and the dielectric trench isolation is recessed from the first level by 0 nm.

3. The memory device of claim 1, wherein the first transistor is a transistor of a complementary metal-oxide semiconductor (CMOS) device and the second transistor is a transistor of another CMOS device.

4. The memory device of claim 1, wherein the first transistor and the second transistor are located in a sense amplifier in the periphery.

5. The memory device of claim 1, wherein the first transistor and the second transistor are located in a pitch device in the periphery.

6. A method of forming a memory device, the method comprising:
forming a first complementary metal-oxide semiconductor (CMOS) device and a second CMOS device in an active area region, the second CMOS device directly adjacent the first CMOS device; and
forming a dielectric trench isolation separating the first CMOS device from the second CMOS device, after forming the first CMOS device and the second CMOS device.

7. The method of claim 6, wherein the method includes forming the dielectric trench isolation after forming source/drain regions of the first CMOS device and the second CMOS device.

8. The method of claim 6, wherein forming the dielectric trench isolation includes:
forming a trench between the first CMOS device and the second CMOS device; and
filling the trench with a low-k dielectric.

9. The method of claim 8, wherein the method includes filling the trench using atomic layer deposition.

10. The method of claim 8, wherein the low-k dielectric includes a nitride.

11. A method of forming a memory device, the method comprising:
forming an island for active areas within a dielectric region;
forming gate stacks for multiple complementary metal-oxide semiconductor (CMOS) devices on active areas of the island;
cutting the island at locations between CMOS devices, forming trenches between CMOS devices;
filling the trenches with a dielectric; and
forming contacts to transistors of the CMOS devices.

12. The method of claim 11, wherein forming the gate stacks includes forming high-k gates.

13. The method of claim 11, wherein cutting the island includes forming the trench with a rectangular shape.

14. The method of claim 11, wherein cutting the island includes removing material between a transistor of one CMOS device and a transistor of a directly adjacent CMOS device on the island such that an opening is formed having a width at top of the island equal to a width of the island.

15. The method of claim 11, wherein filling the trenches includes forming a low-k dielectric in the trenches.

16. The method of claim 15, wherein the method including filling the trenches using atomic layer deposition.

17. The method of claim 15, wherein the low-k dielectric includes a nitride.

18. The method of claim 15, wherein the method includes performing a chemical mechanical planarization procedure on top surfaces of the low-k dielectric.

19. The method of claim 11, wherein filling the trenches forms dielectric trench isolations between directly adjacent CMOS devices such that top surfaces of the active areas of the CMOS devices extend to the dielectric trench isolations with interfaces of the extended top surfaces at the dielectric trench isolations are recessed at most 50 nm.

20. The method of claim 19, wherein the interfaces of the extended top surfaces and the dielectric trench isolations are recessed by 0 nm.
